(19) United States
(12) Patent Application Publication
(10) Pub. No.: US 2009/0194024 A1
(43) Pub. Date: Aug. 6, 2009

(54) CVD APPARATUS

(75) Inventors: Brian H. Burrows, San Jose, CA (US); Ronald Stevens, San Ramon, CA (US); Jacob Grayson, Santa Clara, CA (US); Joshua J. Podesta, Sacramento, CA (US); Sandeep Nijhawan, Los Altos, CA (US); Lori D. Washington, Union City, CA (US); Alexander Tam, Union City, CA (US); Sumedh Acharya, Shahjahanpur (IN)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/023,520

(22) Filed: Jan. 31, 2008

(51) Int. Cl. C23C 16/52; C23C 16/46

(52) U.S. Cl. 118/712; 118/719; 118/725

(57) ABSTRACT

Embodiments of the present invention generally relate to methods and apparatus for chemical vapor deposition (CVD) on a substrate, and, in particular, to a process chamber and components for use in metal organic chemical vapor deposition. The apparatus comprises a chamber body defining a process volume. A showerhead in a first plane defines a top portion of the process volume. A carrier plate extends across the process volume in a second plane forming an upper process volume between the showerhead and the susceptor plate. A transparent material in a third plane defines a bottom portion of the process volume forming a lower process volume between the carrier plate and the transparent material. A plurality of lamps forms one or more zones located below the transparent material. The apparatus provides uniform precursor flow and mixing while maintaining a uniform temperature over larger substrates thus yielding a corresponding increase in throughput.

### BACKGROUND OF THE INVENTION

1. Field of the Invention

Embodiments of the present invention generally relate to methods and apparatus for chemical vapor deposition (CVD) on a substrate, and, in particular, to a process chamber for use in chemical vapor deposition.

2. Description of the Related Art

Group III-V films are finding greater importance in the development and fabrication of a variety of semiconductor devices, such as short wavelength light emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group Ill-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, comprising Group II-VI elements.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface. The quality of the film depends in part upon deposition uniformity which, in turn, depends upon uniform flow and mixing of the precursors across the substrate.

As the demand for LEDs, LDs, transistors, and integrated circuits increases, the efficiency of depositing high quality Group-III nitride films takes on greater importance. Therefore, there is a need for an improved deposition apparatus and process that can provide uniform precursor mixing and consistent film quality over larger substrates and larger deposition areas.

### SUMMARY OF THE INVENTION

The present invention generally relates to methods and apparatus for chemical vapor deposition (CVD) on a substrate, and, in particular, to a process chamber and components for use in chemical vapor deposition.

In one embodiment an apparatus for metal organic chemical vapor deposition on a substrate is provided. The process apparatus comprises a chamber body defining a process volume. A showerhead in a first plane defines a top portion of the process volume. A substrate carrier plate extends across the process volume in a second plane forming an upper process volume between the showerhead and the susceptor plate. A transparent material in a third plane defines a bottom portion of the process volume forming a lower process volume between the substrate carrier plate and the transparent material. A plurality of lamps forms one or more zones located below the transparent material. The plurality of lamps direct radiant heat toward the substrate carrier plate creating one or more radiant heat zones.

In another embodiment a substrate processing apparatus for metal organic chemical vapor deposition is provided. The process apparatus comprises a chamber body defining a process volume. A showerhead in a first plane defines a top portion of the process volume. A substrate carrier plate extends across the process volume in a second plane below the first plane within the process volume. A light shield comprising an angled portion surrounds the periphery of the substrate carrier plate wherein the light shield directs radiant heat toward the substrate carrier plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a deposition chamber according to one embodiment of the invention;

FIG. 2 is a partial cross-sectional view of the deposition chamber of FIG. 1;

FIG. 3 is a perspective view of a carrier plate according to one embodiment of the invention;

FIG. 4A is a perspective view of an upper surface of a susceptor plate according to one embodiment of the invention;

FIG. 4B is a perspective view of a lower surface of the susceptor plate according to one embodiment of the invention;

FIG. 5A is a perspective view of a susceptor support shaft according to one embodiment of the invention;

FIG. 5B is a perspective view of a susceptor support shaft according to another embodiment of the invention;

FIG. 5C is a perspective view of a susceptor support shaft according to another embodiment of the invention;

FIG. 6 is a perspective view of a carrier lift shaft according to one embodiment of the invention;

FIG. 7 is a schematic view of an exhaust process kit according to one embodiment of the invention;

FIG. 8A is a perspective view of an upper liner according to one embodiment of the invention; and

FIG. 8B is a perspective view of a lower liner according to one embodiment of the invention.

### DETAILED DESCRIPTION

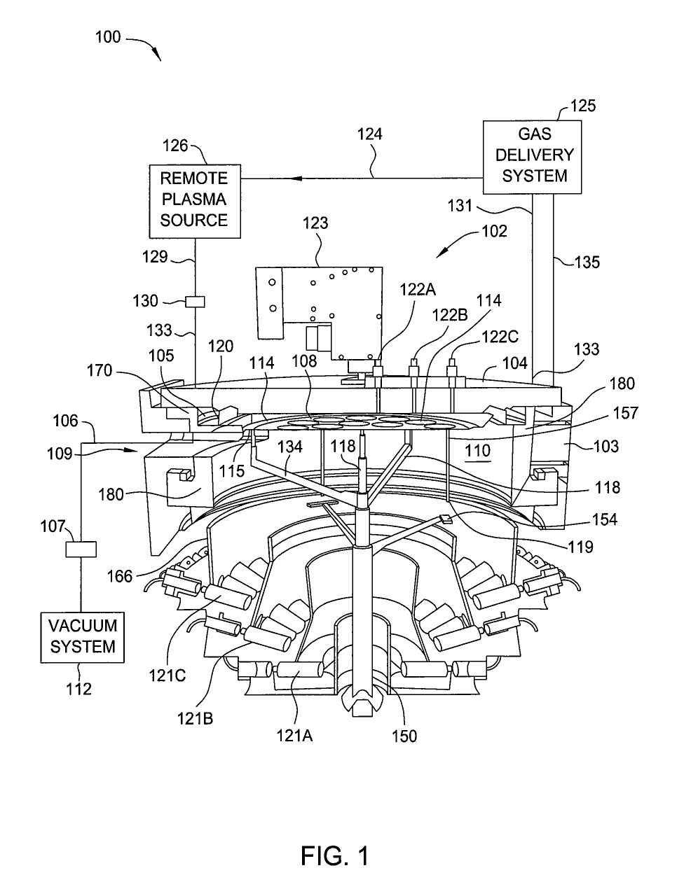

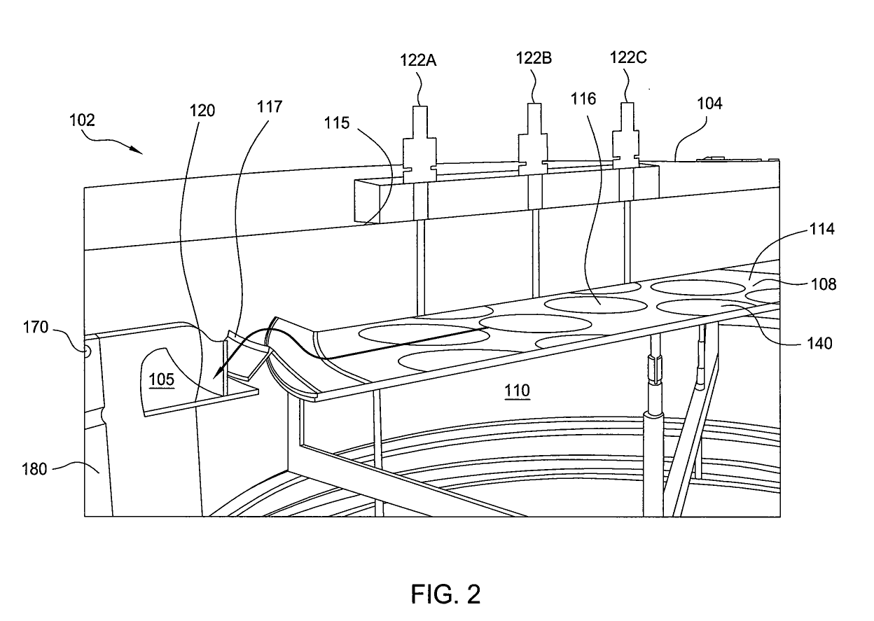

Embodiments of the present invention generally provide a method and apparatus that may be utilized for deposition of Group III-nitride films using MOCVD. Although discussed with reference to MOCVD, embodiments of the present invention are not limited to MOCVD. FIG. 1 is a cross-sectional view of a deposition apparatus that may be used to practice the invention according to one embodiment of the invention. FIG. 2 is a partial cross-sectional view of the deposition chamber of FIG. 1. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

With reference to FIG. 1 and FIG. 2, the apparatus 100 comprises a chamber 102, a gas delivery system 125, a remote plasma source 126, and a vacuum system 112. The chamber 102 includes a chamber body 103 that encloses a processing volume 108. The chamber body 103 may comprise materials such as stainless steel or aluminum. A showerhead assembly 104 or gas distribution plate is disposed at one end of the processing volume 108, and a carrier plate 114 is disposed at the other end of the processing volume 108. Exemplary showerheads that may be adapted to practice the present invention are described in U.S. patent application Ser. No. 11/873,132, filed Oct. 16, 2007, titled MULTI-GAS STRAIGHT CHANNEL SHOWERHEAD, Ser. No. 11/873,141, filed Oct. 16, 2007, titled MULTI-GAS STRAIGHT CHANNEL SHOWERHEAD, and Ser. No. 11/873,170, filed Oct. 16, 2007, titled MULTI-GAS CONCENTRIC INJECTION SHOWERHEAD, all of which are incorporated by reference in their entireties. A transparent material 119, configured to allow light to pass through for radiant heating of substrates 140, is disposed at one end of a lower volume 110 and the carrier plate 114 is disposed at the other end of the lower volume 110. The transparent material 119 may be dome shaped. The carrier plate 114 is shown in process position, but may be moved to a lower position where, for example, the substrates 140 may be loaded or unloaded.

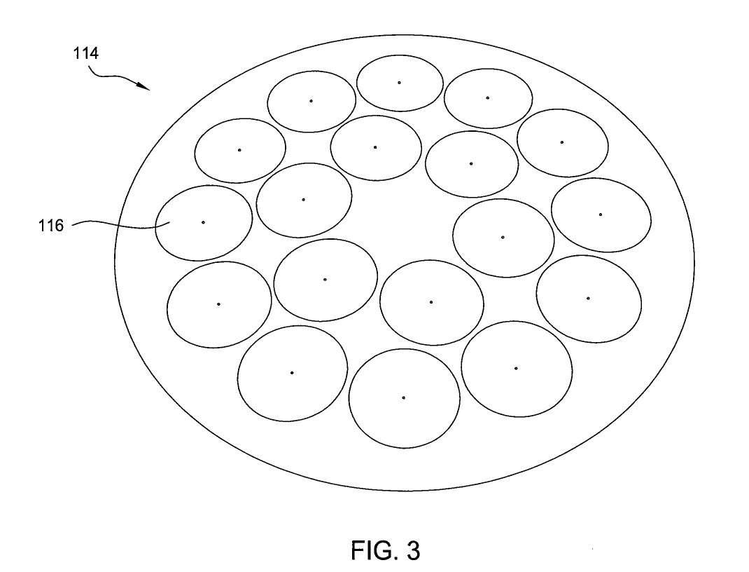

FIG. 3 is a perspective view of a carrier plate according to one embodiment of the invention. In one embodiment, the carrier plate 114 may include one or more recesses 116 within which one or more substrates 140 may be disposed during processing. In one embodiment, the carrier plate 114 is configured to carry six or more substrates 140. In another embodiment, the carrier plate 114 is configured to carry eight substrates 140. In another embodiment, the carrier plate 114 is configured to carry 18 substrates. In yet another embodiment, the carrier plate 114 is configured to carry 22 substrates. It is to be understood that more or less substrates 140 may be carried on the carrier plate 114. Typical substrates 140 may include sapphire, silicon carbide (SiC), silicon, or gallium nitride (GaN). It is to be understood that other types of substrates 140, such as glass substrates 140, may be processed. Substrate 140 size may range from 50 mm-100 mm in diameter or larger. The carrier plate 114 size may range from 200 mm-750 mm. The carrier plate 114 may be formed from a variety of materials, including SiC or SiC-coated graphite. It is to be understood that substrates 140 of other sizes may be processed within the chamber 102 and according to the processes described herein.

The carrier plate 114 may rotate about an axis during processing. In one embodiment, the carrier plate 114 may be rotated at about 2 RPM to about 100 RPM. In another embodiment, the carrier plate 114 may be rotated at about 30 RPM. Rotating the carrier plate 114 aids in providing uniform heating of the substrates 140 and uniform exposure of the processing gases to each substrate 140. In one embodiment, the carrier plate 114 is supported by a carrier supporting device comprising a susceptor plate 115. Exemplary substrate support structures that may be adapted to practice the present invention are described in U.S. patent application Ser. No. 11/552,474, filed Oct. 24, 2006, titled SUBSTRATE SUPPORT STRUCTURE WITH RAPID TEMPERATURE CHANGE, which IS incorporated by reference in its entirety.

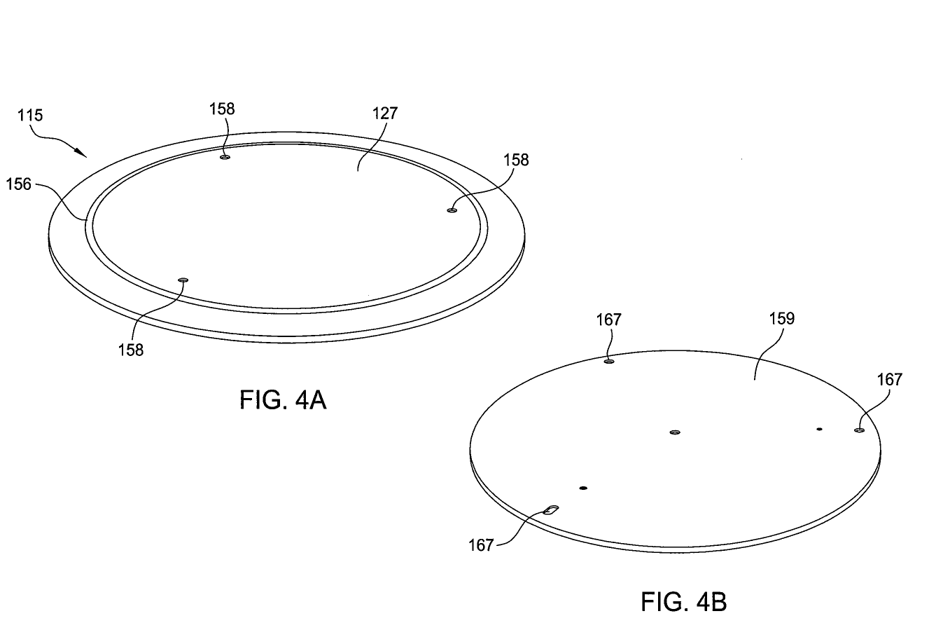

FIG. 4A is a perspective view of an upper surface of a susceptor plate according to one embodiment of the invention. FIG. 4B is a perspective view of a lower surface of the susceptor plate according to one embodiment of the invention. The susceptor plate 115 has a disk form and is made of a graphite material coated with silicon carbide. The upper surface 156 of the susceptor plate 115 is formed with a circular recess 127. The circular recess 127 acts as a support area for accommodating and supporting the carrier plate 114. The susceptor plate 115 has three throughholes 158 for accommodating lift pins. The susceptor plate 115 is horizontally supported at three points from the underside by a susceptor support shaft 118 made of quartz disposed in the lower volume 110 of the chamber. The lower surface 159 of the susceptor plate has three holes 167 for accommodating the lift arms of the susceptor support shaft 118. Although the susceptor plate 115 is described as having three holes 167, any number of holes corresponding to the number of lift arms of the susceptor support shaft 118 may be used.

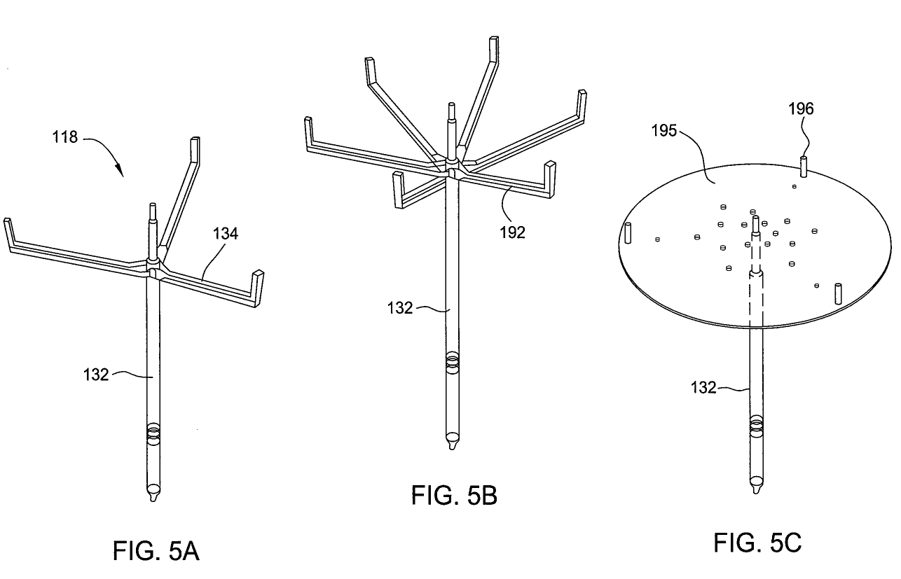

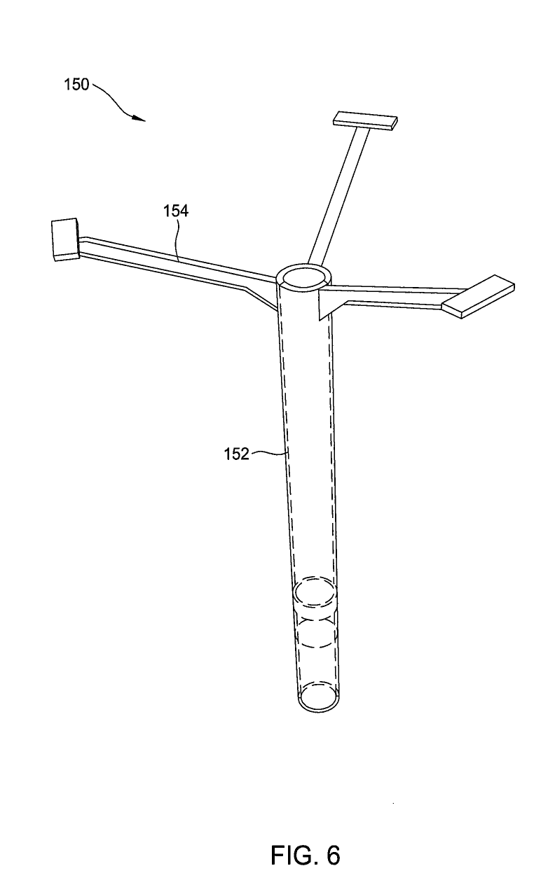

The lift mechanism 150 will be discussed with respect to FIGS. 5A-5C and FIG. 6. FIG. 5A is a perspective view of the susceptor support shaft and FIG. 6 is a perspective view of a carrier plate lift mechanism. The susceptor support shaft 118 comprises a central shaft 132 with three lift arms 134 extending radially from the central shaft 132. Although the susceptor support shaft 118 is shown with three lift arms 134, any number of lift arms greater than three may also be used, for example, the susceptor support shaft 118 may comprise six lift arms 192 as depicted in FIG. 5B. In one embodiment depicted in FIG. 5C the lift arms are replace by a disk 195 with support posts 196 extending from the surface of the disk 195 to support the susceptor plate 115.

The carrier plate lift mechanism 150 comprises a vertically movable lift tube 152 arranged so as to surround the central shaft 132 of the susceptor support shaft 118, a driving unit (not shown) for moving the lift tube 152 up and down, three lift arms 154 radially extending from the lift tube 152, and lift pins 157 suspended from the bottom surface of the susceptor plate 115 by way of respective throughholes 158 formed so as to penetrate therethrough. When the driving unit is controlled so as to raise the lift tube 152 and lift arms 154 in such a configuration, the lift pins 157 are pushed up by the distal ends of the lift arms 154 whereby the carrier plate 114 rises.

As shown in FIG. 1, radiant heating may be provided by a plurality of inner lamps 121A, a plurality of central lamps 121B, and a plurality of outer lamps 121C disposed below the lower dome 119. Reflectors 166 may be used to help control chamber 102 exposure to the radiant energy provided by the inner, central, and outer lamps 121A, 121B, 121C. Additional zones of lamps may also be used for finer temperature control of the substrates 140. In one embodiment, the reflectors 166 are coated with gold. In another embodiment, the reflectors 166 are coated with aluminum, rhodium, nickel, combinations thereof, or other highly reflective materials. In one embodiment, there are 72 lamps total comprising 24 lamps per zone at 2 kilowatts per lamp. In one embodiment, the lamps are air-cooled and the bases of the lamps are water cooled.

The plurality of inner lamps, central lamps, and outer lamps 121A, 121B, 121C may be arranged in concentric zones or other zones (not shown), and each zone may be separately powered allowing for the tuning of deposition rates and growth rates through temperature control. In one embodiment, one or more temperature sensors, such as pyrometers 122A, 122B, 122C, may be disposed within the showerhead assembly 104 to measure substrate 140 and carrier plate 114 temperatures, and the temperature data may be sent to a controller (not shown) which can adjust power to each zone to maintain a predetermined temperature profile across the carrier plate 114. In one embodiment, an inert gas is flown around the pyrometers 122A, 122B, 122C into the processing volume 108 to prevent deposition and condensation from occurring on the pyrometers 122A, 122B, 122C. The pyrometers 122A, 122B, 122C can compensate automatically for changes in emissivity due to deposition on surfaces. Although three pyrometers 122A, 122B, 122C are shown, it should be understood that any numbers of pyrometers may be used, for example, if additional zones of lamps are added it may be desirable to add additional pyrometers to monitor each additional zone. In another embodiment, the power to separate lamp zones may be adjusted to compensate for precursor flow or precursor concentration non-uniformity. For example, if the precursor concentration is lower in a carrier plate 114 region near an outer lamp zone, the power to the outer lamp zone may be adjusted to help compensate for the precursor depletion in this region. Advantages of using lamp heating over resistive heating include a smaller temperature range across the carrier plate 114 surface which improves product yield. The ability of lamps to quickly heat up and quickly cool down increases throughput and also helps create sharp film interfaces.

Other metrology devices, such as a reflectance monitor 123, thermocouples (not shown), or other temperature devices may also be coupled with the chamber 102. The metrology devices may be used to measure various film properties, such as thickness, roughness, composition, temperature or other properties. These measurements may be used in an automated real-time feedback control loop to control process conditions such as deposition rate and the corresponding thickness. In one embodiment, the reflectance monitor 123 is coupled with the showerhead assembly 104 via a central conduit (not shown). Other aspects of the chamber metrology are described in U.S. patent application Ser. No. ______, filed Jan. 31, 2008, (attorney docket no. 011007) entitled CLOSED LOOP MOCVD DEPOSITION CONTROL, which is herein incorporated by reference in its entirety.

The inner, central, and outer lamps 121A, 121B, 121C may heat the substrates 140 to a temperature of about 400 degrees Celsius to about 1200 degrees Celsius. It is to be understood that the invention is not restricted to the use of arrays of inner, central, and outer lamps 121A, 121B, and 121C. Any suitable heating source may be utilized to ensure that the proper temperature is adequately applied to the chamber 102 and substrates 140 therein. For example, in another embodiment, the heating source may comprise resistive heating elements (not shown) which are in thermal contact with the carrier plate 114.

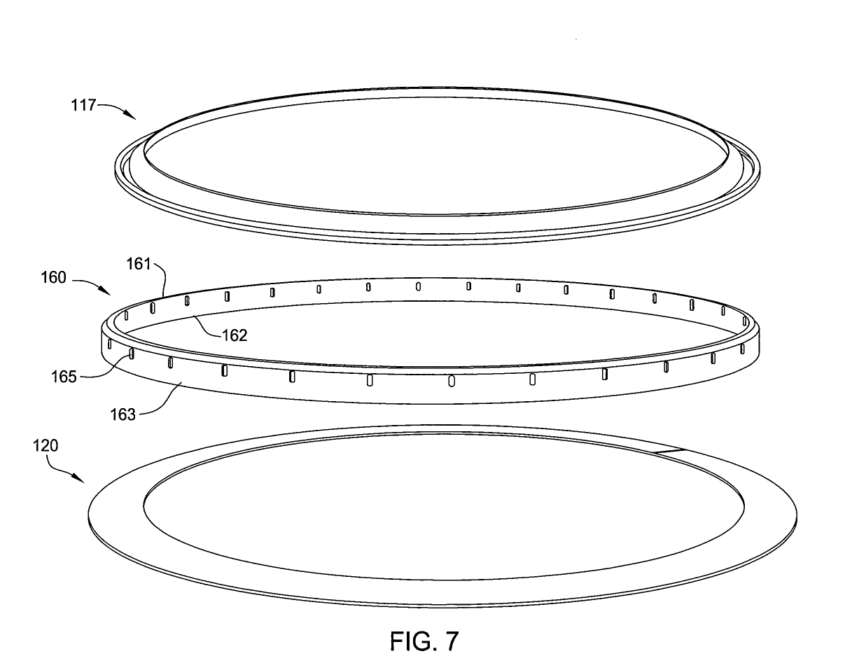

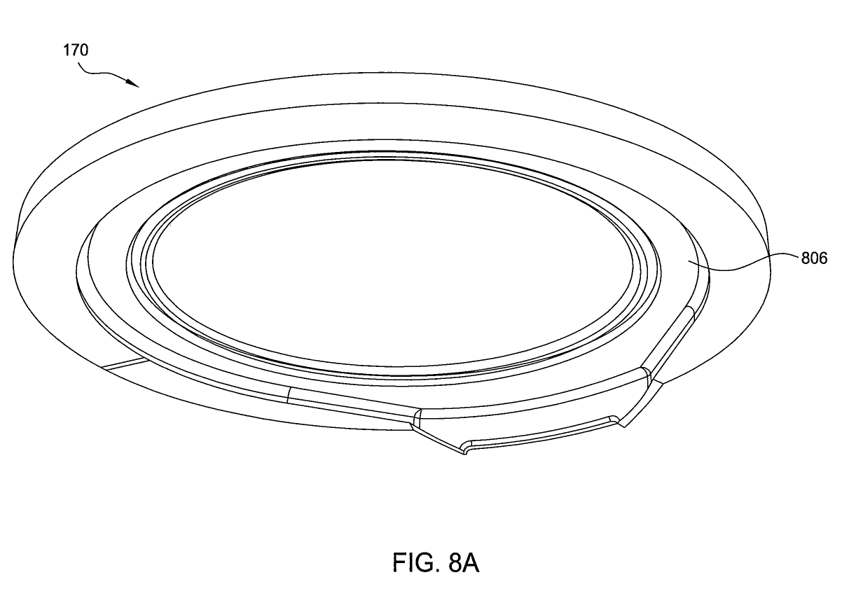

With reference to FIG. 2 and FIG. 7, FIG. 7 is a perspective view of an exhaust process kit according to one embodiment of the invention. In one embodiment, the process kit may comprise a light shield 117, an exhaust ring 120, and an exhaust cylinder 160. As shown in FIG. 2, the light shield 117 may be disposed around the periphery of the carrier plate 114. The light shield 117 absorbs energy that strays outside of the susceptor diameter from the inner lamps 121A, the central lamps 121B, and the outer lamps 121C and helps redirect the energy toward the interior of the chamber 102. The light shield 117 also blocks direct lamp radiant energy from interfering with metrology tools. In one embodiment, the light shield 117 generally comprises an annular ring with an inner edge and an outer edge. In one embodiment, the outer edge of the annular ring is angled upward. The light shield 117 generally comprises silicon carbide. The light shield 117 may also comprise alternative materials that absorb electromagnetic energy, such as ceramics. The light shield 117 may be coupled with the exhaust cylinder 160, the exhaust ring 120 or other parts of the chamber body 103. The light shield 117 generally does not contact the susceptor plate 115 or carrier plate 114.

In one embodiment, the exhaust ring 120 may be disposed around the periphery of the carrier plate 114 to help prevent deposition from occurring in the lower volume 110 and also help direct exhaust gases from the chamber 102 to exhaust ports 109. In one embodiment, the exhaust ring 120 comprises silicon carbide. The exhaust ring 120 may also comprise alternative materials that absorb electromagnetic energy, such as ceramics.

In one embodiment, the exhaust ring 120 is coupled with an exhaust cylinder 160. In one embodiment, the exhaust cylinder 160 is perpendicular to the exhaust ring 120. The exhaust cylinder 160 helps maintain uniform and equal radial flow from the center outward across the surface of the carrier plate 114 and controls the flow of gas out of process volume 108 and into the annular exhaust channel 105. The exhaust cylinder 160 comprises an annular ring 161 having an inner sidewall 162 and an outer side wall 163 with throughholes or slots 165 extending through the sidewalls and positioned at equal intervals throughout the circumference of the ring 161. In one embodiment, the exhaust cylinder 160 and the exhaust ring 120 comprise a unitary piece. In one embodiment the exhaust ring 120 and the exhaust cylinder 160 comprise separate pieces that may be coupled together using attachment techniques known in the art. With reference to FIG. 2, process gas flows downward from the showerhead assembly 104 toward the carrier plate 114 and travels radially outward over the light shield 117, through the slots 165 in the exhaust cylinder 160 and into the annular exhaust channel 105 where it eventually exits the chamber 102 via exhaust port 109. The slots in the exhaust cylinder 160 choke the flow of the process gas helping to achieve uniform radial flow over the entire susceptor plate 115. In one embodiment, inert gas flows upward through a gap formed between the light shield 117 and the exhaust ring 120 to prevent process gas from entering the lower volume 110 of the chamber 102 and depositing on the lower dome 119. Deposition on the lower dome 119 may affect temperature uniformity and in some cases may heat the lower dome 119 causing it to crack.

A gas delivery system 125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 102. Different gases, such as precursor gases, carrier gases, purge gases, cleaning/etching gases or others may be supplied from the gas delivery system 125 to separate supply lines 131, 135 to the showerhead assembly 104. The supply lines may include shut-off valves and mass flow controllers or other types of controllers to monitor and regulate or shut off the flow of gas in each line. In one embodiment, precursor gas concentration is estimated based on vapor pressure curves and temperature and pressure measured at the location of the gas source. In another embodiment, the gas delivery system 125 includes monitors located downstream of the gas sources which provide a direct measurement of precursor gas concentrations within the system.

A conduit 129 may receive cleaning/etching gases from a remote plasma source 126. The remote plasma source 126 may receive gases from the gas delivery system 125 via a supply line 124, and a valve 130 may be disposed between the shower head assembly 104 and remote plasma source 126. The valve 130 may be opened to allow a cleaning and/or etching gas or plasma to flow into the shower head assembly 104 via supply line 133 which may be adapted to function as a conduit for a plasma. In another embodiment, cleaning/etching gases may be delivered from the gas delivery system 125 for non-plasma cleaning and/or etching using alternate supply line configurations to shower head assembly 104. In yet another embodiment, the plasma bypasses the shower head assembly 104 and flows directly into the processing volume 108 of the chamber 102 via a conduit (not shown) which traverses the shower head assembly 104.

The remote plasma source 126 may be a radio frequency or microwave plasma source adapted for chamber 102 cleaning and/or substrate 140 etching. Cleaning and/or etching gas may be supplied to the remote plasma source 126 via supply line 124 to produce plasma species which may be sent via conduit 129 and supply line 133 for dispersion through showerhead assembly 104 into chamber 102. Gases for a cleaning application may include fluorine, chlorine or other reactive elements.

In another embodiment, the gas delivery system 125 and remote plasma source 126 may be suitably adapted so that precursor gases may be supplied to the remote plasma source 126 to produce plasma species which may be sent through showerhead assembly 104 to deposit CVD layers, such as III-V films, for example, on substrates 140.

A purge gas (e.g., nitrogen) may be delivered into the chamber 102 from the showerhead assembly 104 and/or from inlet ports or tubes (not shown) disposed below the carrier plate 114 and near the bottom of the chamber body 103. The purge gas enters the lower volume 110 of the chamber 102 and flows upwards past the carrier plate 114 and exhaust ring 120 and into multiple exhaust ports 109 which are disposed around an annular exhaust channel 105. An exhaust conduit 106 connects the annular exhaust channel 105 to a vacuum system 112 which includes a vacuum pump (not shown). The chamber 102 pressure may be controlled using a valve system 107 which controls the rate at which the exhaust gases are drawn from the annular exhaust channel 105.

The showerhead assembly 104 is located near the carrier plate 114 during substrate 140 processing. In one embodiment, the distance from the showerhead assembly 104 to the carrier plate 114 during processing may range from about 4 mm to about 40 mm.

During substrate processing, according to one embodiment of the invention, process gas flows from the showerhead assembly 104 towards the surface of the substrate 140. The process gas may comprise one or more precursor gases as well as carrier gases and dopant gases which may be mixed with the precursor gases. The draw of the annular exhaust channel 105 may affect gas flow so that the process gas flows substantially tangential to the substrates 140 and may be uniformly distributed radially across the deposition surfaces of the substrate 140 deposition surfaces in a laminar flow. The processing volume 108 may be maintained at a pressure of about 760 Torr down to about 80 Torr.

Reaction of process gas precursors at or near the surface of the substrate 140 may deposit various metal nitride layers upon the substrate 140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl) magnesium (Cp₂Mg or (C₅H₅)₂Mg) for magnesium doping.

In one embodiment, a fluorine or chlorine based plasma may be used for etching or cleaning. In other embodiments, halogen gases, such as Cl₂, Br, and I₂, or halides, such as HCl, HBr, and HI, may be used for non-plasma etching.

In one embodiment, a carrier gas, which may comprise nitrogen gas (N₂), hydrogen gas (H₂), argon (Ar) gas, another inert gas, or combinations thereof may be mixed with the first and second precursor gases prior to delivery to the showerhead assembly 104.

In one embodiment, the first precursor gas may comprise a Group III precursor, and second precursor gas may comprise a Group V precursor. The Group III precursor may be a metal organic (MO) precursor such as trimethyl gallium (“TMG”), triethyl gallium (TEG), trimethyl aluminum (“TMAI”), and/or trimethyl indium (“TMI”), but other suitable MO precursors may also be used. The Group V precursor may be a nitrogen precursor, such as ammonia (NH₃).

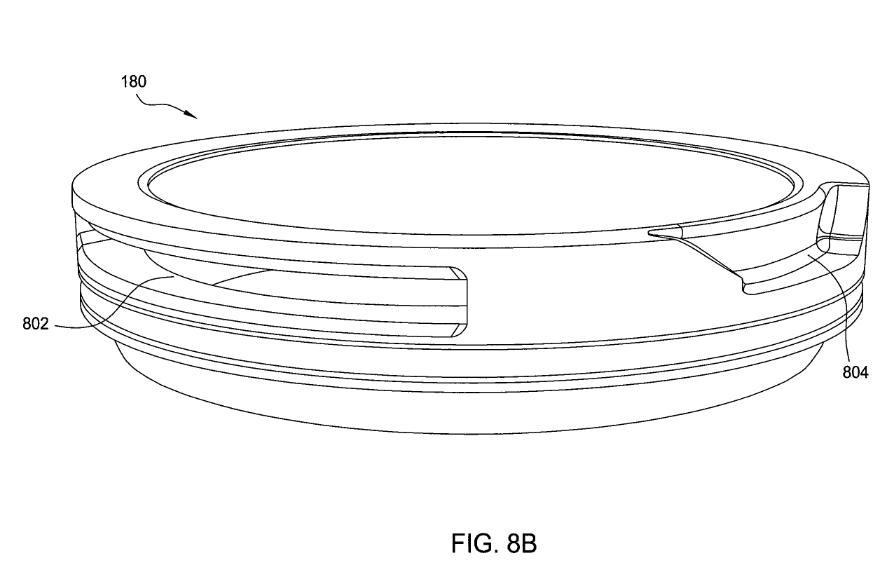

FIG. 8A is a perspective view of an upper liner according to one embodiment of the invention. FIG. 8B is a perspective view of a lower liner according to one embodiment of the invention. In one embodiment, the process chamber 102 further comprises an upper process liner 170 and a lower process liner 180 which help protect the chamber body 103 from etching by process gases. In one embodiment, the upper process liner 170 and the lower process liner 180 comprise a unitary body. In another embodiment, the upper process liner 170 and the lower process liner 180 comprise separate pieces. The lower process liner 180 is disposed in the lower volume 110 of the process chamber 102 and upper process liner 170 is disposed adjacent to the showerhead assembly 104. In one embodiment, the upper process liner 170 rests on the lower process liner 180. In one embodiment, lower liner 170 has a slit valve port 802 and an exhaust port 804 opening which may form a portion of exhaust port 109. The upper process liner 170 has an exhaust annulus 806 which may form a portion of annular exhaust channel 105. The liners may comprise thermally insulating material such as opaque quartz, sapphire, PBN material, ceramic, derivatives thereof or combinations thereof.

An improved deposition apparatus and process that provides uniform precursor flow and mixing while maintaining a uniform temperature over larger substrates and larger deposition areas has been provided. The uniform mixing and heating over larger substrates and/or multiple substrates and larger deposition areas is desirable in order to increase yield and throughput. Further uniform heating and mixing are important factors since they directly affect the cost to produce an electronic device and, thus, a device manufacturer's competitiveness in the market place.

While the foregoing is directed to embodiments of the present invention, other and further embodiments of the invention may be devised without departing from the basic scope thereof, and the scope thereof is determined by the claims that follow.

1. A substrate processing apparatus for metal organic chemical vapor deposition, comprising:
a chamber body forming a process volume;
a showerhead in a first plane defining a top portion of the process volume;
a substrate carrier plate in a second plane below the first plane, the carrier plate extending across the process volume defining an upper process volume between the showerhead and the substrate carrier plate;
a transparent material in a third plane defining a bottom portion of the process volume and forming a lower process volume between the carrier plate and the transparent material; and
a plurality of lamps forming one or more zones located below the transparent material and adapted to direct radiant heat toward the carrier plate creating one or more radiant heat zones.

2. The apparatus of claim 1, wherein the one or more zones comprises an inner zone, a central zone, and an outer zone.

3. The apparatus of claim 2, wherein each zone forms a concentric array of lamps.

4. The apparatus of claim 3, wherein the outer zone is located above the central zone.

5. The apparatus of claim 1, wherein the power supplied to each zone of lamps is separately controlled.

6. The apparatus of claim 1, wherein the one or more zones of lamps comprise one or more reflectors adapted to direct radiant heat toward the substrate carrier plate.

7. The apparatus of claim 6, wherein the one or more reflectors have a gold coating.

8. The apparatus of claim 1, further comprising one or more pyrometers for monitoring each of the one or more radiant heat zones to adjust power to each separate lamp zone and maintain a predetermined temperature profile across the substrate carrier.

9. The apparatus of claim 8, wherein the one or more pyrometers are purged by flowing an inert gas around the pyrometers to prevent deposition and condensation from occurring on the pyrometers

10. The apparatus of claim 1, wherein the substrate carrier plate has multiple recesses for receiving multiple substrates.

11. The apparatus of claim 1, wherein the substrate carrier plate is supported by a susceptor plate having a circular recess adapted to hold the substrate carrier.

12. The apparatus of claim 1, further comprising a reflectance monitor coupled with the chamber body.

13. The apparatus of claim 1, further comprising a gas delivery system with gas sources for supplying cleaning gas, etching gas, and/or plasma to the showerhead.

14. The apparatus of claim 1, wherein a gas delivery system comprises gas monitors located downstream of the gas sources which provide a direct measurement of precursor gas concentrations within the system.

15. A substrate processing apparatus for metal organic chemical vapor deposition, comprising:
a chamber body forming a process volume;
a showerhead defining a top portion of the process volume;
a substrate carrier plate extending across the process volume defining a bottom portion of the process volume; and
a light shield surrounding the substrate carrier, wherein the light shield directs radiant heat toward the substrate carrier.

16. The apparatus of claim 15, further comprising a plurality of lamps forming one or more concentric zones of lamps located below the carrier plate and adapted to direct radiant heat toward the carrier plate creating one or more radiant heat zones.

17. The apparatus of claim 16, further comprising an exhaust ring surrounding the periphery of the light shield.

18. The apparatus of claim 17, further comprising an exhaust cylinder coupled with the exhaust ring, wherein the exhaust cylinder has a plurality of slots positioned at equal intervals.

19. The apparatus of claim 18, wherein an annular exhaust passage surrounds the periphery of the exhaust cylinder.

20. The apparatus of claim 15, wherein the substrate carrier plate has multiple recesses for receiving one or more substrates.
